(19) United States
(12) Patent Application Publication
(10) Pub. No.: US 2007/0187668 A1
(43) Pub. Date: Aug. 16, 2007

(54) Crystal substrates and methods of fabricating the same

(76) Inventors: Takashi Noguchi, Yongin-si (KR); Hans S. Cho, Seoul (KR); Wenxu Xianyu, Suwon-si (KR); Huaxiang Yin, Yongin-si (KR)

Correspondence Address: HARNESS, DICKEY & PIERCE, P.L.C., P.O. BOX 8910, RESTON, VA, 20195, US

(21) Appl. No.: 11/598,040

(22) Filed: Nov. 13, 2006

(30) Foreign Application Priority Data
Feb. 16, 2006 (KR) 10-2006-0015151

(51) Int. Cl. H01L 31/00; C30B 13/02; C30B 19/00; H01L 29/04

(52) U.S. Cl. 257/19; 257/55; 257/64; 117/89; 117/53; 117/56

(57) ABSTRACT

A single crystal substrate and method of fabricating the same are provided. The single crystal substrate includes an insulator having a window exposing a portion of a substrate, a selective epitaxial growth layer formed on the portion of the substrate exposed through the window and a single crystalline layer formed on the insulator and the selective epitaxial growth layer using the selective epitaxial growth layer as an epitaxial seed layer.

### PRIORITY STATEMENT

This non-provisional U.S. patent application claims priority under 35 U.S.C. §119 to Korean Patent Application No. 10-2006-0015151, filed on Feb. 16, 2006, in the Korean Intellectual Property Office (KIPO), the entire contents of which is incorporated herein by reference.

### BACKGROUND

### Description of the Related Art

Size reduction of related art semiconductor devices may be limited because of a performance limitation on wafer-type single crystal silicon. For example, wafer-type single crystal silicon used in related art semiconductor devices may reach a performance breaking point due to compactness of transistors. In the related art, silicon on insulators (SOIs) have been used to attempt to suppress this limitation. SOIs are formed by depositing single crystal silicon on insulators to improve the performance of the elements without reducing the dimensions of the elements.

SOIs are single crystal silicon substrates that are parasitic, have a high mobility and have lower power consumption capable of reducing capacitances and short-channel effects, for example, reducing cross-talk. High-performance SOIs may be stacked 3-dimensionally, for example, in piles to dispose a plurality of elements in an area of a substrate to improve semiconductor chip performance and/or element density. Also, a 3-dimensionally stacked structure in which single crystal silicon layers are stacked in piles, but insulated from one another by insulating layers, may produce an improved structure. However, related art methods of fabricating single layer SOI substrates may have relative high fabricating costs. In addition, if single layer SOI substrates are stacked in several layers, the fabricating cost may increase. Furthermore, elements fabricated on a lower layer may break while fabricating an upper layer (e.g., a single crystal stacked layer).

An example related art method of fabricating an SOI is a method of fabricating an SOI wafer including a higher temperature annealing process performed at a maximum temperature of 1000° C. This related art method includes a process of annealing an initially bare wafer having a thickness sufficient to coat an oxide layer, a process of injecting hydrogen (H⁺) ions under the surface of the bare wafer to form a boundary layer of hydrogen impurities, a process of bonding the bare wafer to an additional substrate in order to separate the boundary layer from the bare wafer so that silicon having a thickness remains on the additional substrate, a higher temperature annealing process, etc.

In the above-mentioned related art method, the temperature is 900° C. during thermal oxidization and 1100° C. during annealing, each of which may exert a relatively high load on the substrate. In addition, the substrate formed may experience a thermal impact while enduring the higher temperature process. As a result, the substrate material used may be critical.

A semiconductor device produced from a substrate that experienced a thermal impact may be more likely to have natural defects, and thus, the yield may be lower or relatively low. This may result in a more difficult and/or costly process of producing SOIs. Moreover, the quality of an SOI layer formed at a higher cost may decrease, and it may be more difficult to obtain a higher quality device.

A lateral crystallization or lateral growth method of forming amorphous silicon on a substrate and growing a crystal from an initially formed crystal nucleus (seed) in a lateral direction with respect to the substrate through laser fusing and solidifying processes is another example of a related art method of fabricating an SOI. In a related art lateral crystallization or lateral growth method, a single crystal may be grown in a local target position, and a multilayered single crystal structure may be formed through the lateral crystallization or lateral growth method to produce a three-dimensional (3D) semiconductor device. However, a surface of the single crystal obtained through the lateral growth or lateral crystallization may not be sufficiently smooth. Thus, a process of planarizing the surface of the single crystal is required through, for example, chemical mechanical polishing (CMP).

CMP may require a relatively large amount of time to planarize and polishing depth may be relatively difficult to control. Thus, forming a crystal layer to a target thickness may be more difficult.

### SUMMARY

Example embodiments related to single crystal substrates and methods of fabricating the same. For example, example embodiments provide a single crystal silicon substrate and a single crystal germanium substrate. At least one example embodiment provides a laterally crystallized substrate having more easily controllable thickness and a method of fabricating the same.

According to at least one example embodiment, a single crystal substrate may include a crystalline substrate, a laterally-crystallized crystalline layer parallel to the crystalline substrate and/or a polishing stopper buried in the laterally crystallized crystalline layer. The polishing stopper may limit a polishing depth of the laterally crystallized crystalline layer.

According to at least one example embodiment, a method of fabricating a single crystal substrate may include forming a stopper on a crystalline substrate, forming an amorphous layer burying the stopper on the crystalline substrate, melting and solidifying the amorphous layer to form a crystalline layer crystallized parallel to the crystalline substrate, and polishing the crystalline layer up to an upper portion of the stopper buried in the crystalline layer.

### BRIEF DESCRIPTION OF THE DRAWINGS

Example embodiments will become more apparent by describing in detail the attached drawings in which:

FIGS. 1A and 1B are schematic cross-sectional views illustrating crystal silicon substrates having crystal layers crystallized through lateral thermal gradients, according to an example embodiment;

FIGS. 2A and 2B are schematic cross-sectional views illustrating crystal silicon substrates having lateral crystal layers crystallized through seed layers, according to an example embodiment;

FIGS. 3A and 3B are cross-sectional views illustrating crystal germanium substrates having lateral crystal layers crystallized through seed layers, according to an example embodiment;

FIGS. 4A through 4J are cross-sectional views illustrating a method of fabricating a crystal silicon substrate, according to an example embodiment;

FIG. 5A is a scanning electronic microscopy (SEM) image illustrating a sample of a fabricated crystal silicon substrate, according to an example embodiment;

FIG. 5B is an enlarged image of a square portion of the SEM image illustrated in FIG. 5A, according to an example embodiment;

FIG. 6A is an SEM image illustrating a sample of a successfully crystallized crystal silicon substrate, according to an example embodiment; and

FIG. 6B is an enlarged SEM image of the sample illustrated in FIG. 6A, according to an example embodiment.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions are exaggerated for clarity.

Detailed illustrative example embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while example embodiments are capable of various modifications and alternative forms, embodiments thereof are shown by way of example in the drawings and will herein be described in detail. It should be understood, however, that there is no intent to limit example embodiments to the particular forms disclosed, but on the contrary, example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

It will be understood that when an element or layer is referred to as being “formed on” another element or layer, it can be directly or indirectly formed on the other element or layer. That is, for example, intervening elements or layers may be present. In contrast, when an element or layer is referred to as being “directly formed on” to another element, there are no intervening elements or layers present. Other words used to describe the relationship between elements or layers should be interpreted in a like fashion (e.g., “between” versus “directly between”, “adjacent” versus “directly adjacent”, etc.).

The terminology used herein is for the purpose of describing particular embodiments only and is not intended to be limiting of example embodiments. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

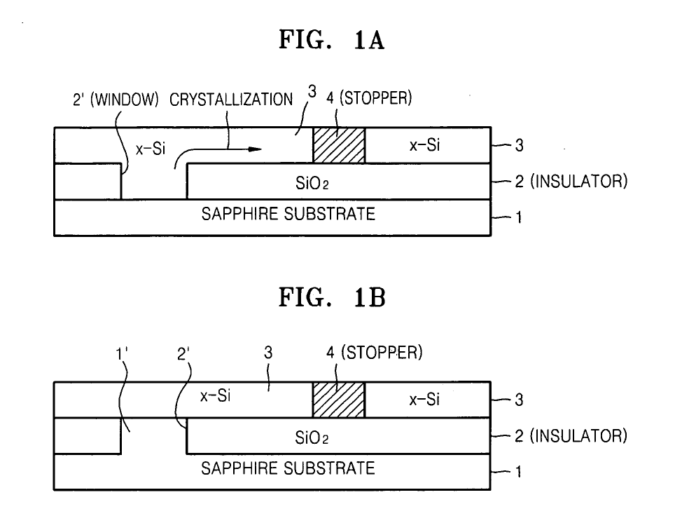

FIGS. 1A and 1B are schematic cross-sectional views illustrating single crystal silicon substrates having crystal layers crystallized through lateral thermal gradients by locally differential cooling, according to an example embodiment.

Referring to FIG. 1A, an insulator 2 having a window 2′ exposing a portion of a surface of a sapphire substrate 1 may be formed on the sapphire substrate 1. A single crystal silicon layer 3 may be formed on the insulator 2.

In at least some example embodiments, a stopper 4 may define a polishing depth for polishing the single crystal silicon layer 3. The stopper 4 may be buried in the single crystal silicon layer 3. In at least this example embodiment, the insulator 2 may have a lower thermal conductivity than the sapphire substrate 1. As a result, when the single crystal silicon layer 3 is formed using amorphous silicon, a lateral thermal gradient may occur in the single crystal silicon layer 3. A crystal nucleus may be generated within the window 2′, and may emit heat (e.g., relatively large amount of heat) due to the lateral thermal gradient. As a result, a crystal may grow upwards from the insulator 2 through the window 2′ as indicated by the arrow in FIG. 1A.

Referring to FIG. 1B, unlike the single crystal silicon substrate shown in FIG. 1A, the single crystal silicon substrate shown in FIG. 1B may have a structure in which a protruding portion 1′ of a sapphire substrate 1 may extend into a window 2′ through an insulator 2. In at least this example embodiment, a lateral thermal gradient may be obtained instead of increases in latent heat and/or a heat transfer caused by the protruding portion 1′.

Single crystal wafers fabricated by crystal nuclei directly formed, but not generated, by thermal gradients, according to at least some example embodiments will now be described.

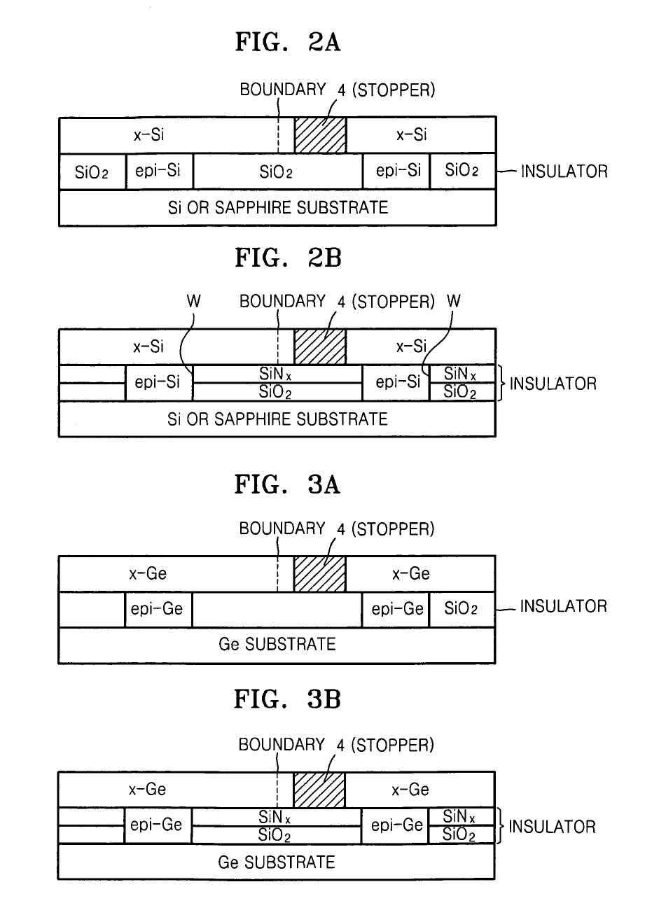

FIGS. 2A and 2B are schematic cross-sectional views illustrating single crystal silicon substrates having lateral crystal layers crystallized through seed layers, according to an example embodiment. Referring to FIG. 2A, a SiO₂ insulator may be formed on a silicon substrate, a sapphire substrate or the like, and a window or a via hole W may be formed in the SiO₂ insulator. A crystal growth silicon layer epi-Si may be formed in the window W through the SiO₂ insulator using, for example, selective epitaxial growth or the like.

Single crystal silicon layers x-Si may be formed on the SiO₂ insulator and the crystal growth silicon layer epi-Si. The single crystal silicon layers x-Si may be formed by crystallizing amorphous silicon. A seed of crystallization may form the single crystal growth silicon layer epi-Si.

Because the crystallization of the single crystal silicon layers x-Si begins from a plurality of seeds, a boundary exists at an intermediate position on the SiO₂ insulator between the single crystal silicon layers x-Si. The single crystal silicon layers x-Si may have more uniform crystal structures on each side of the boundary on the SiO₂ insulator, and a higher quality device may be obtained from the more uniform crystal structures. A stopper 4 may be formed on a wafer. In at least one example embodiment, the stopper 4 may be formed on the SiO₂ insulator. The stopper 4 may be positioned in an area in which a device is not to be formed, for example, an area in which a transistor is not to be formed.

Referring to FIG. 2B, in a single crystal silicon substrate, a SiO₂ insulator may have a multi-layer structure (e.g., a dual layer) structure. In other words, for example, a SiO₂ layer and a SiNₓ layer may be stacked on a silicon or sapphire substrate to form an insulator having an island shape. A window or an aperture W for selective epitaxial growth may be formed in the insulator having the dual layer structure, and a crystal growth silicon layer epi-Si may be formed in the window or aperture W. A crystal boundary and a plurality of single crystal silicon layers may be formed on the SiO₂ insulator and the crystal growth silicon layer epi-Si. In at least this example embodiment, two single crystal silicon layers are formed. However, the insulator may include any number of layers. A stopper 4 buried in a single crystal silicon layer x-Si may be formed on the SiO₂ insulator.

In at least this example embodiment, the SiNₓ layer may be formed of, for example, Si₃N₄ to suppress (e.g., inhibit and/or prevent) an agglomeration of Si caused by surface tension during a process of crystallizing a silicon material. This may produce a higher quality single crystal silicon layer x-Si. Although Si₃N₄ is discussed above, the layer may be any known material having surface boundary energy, such as SiNₓ.

FIGS. 3A and 3B are cross-sectional views illustrating single crystal germanium substrates having lateral crystal layers crystallized through seed layers, according to an example embodiment. Referring to FIG. 3A, a SiO₂ insulator may be formed on a single crystal germanium substrate, and a window or via hole may be formed through the SiO₂ insulator. A crystal growth germanium layer epi-Ge may be formed within the window or via hole using, for example, selective epitaxial growth. A stopper 4 may be formed on the SiO₂ insulator.

Single crystal germanium layers x-Ge may be formed on the SiO₂ insulator and the crystal growth germanium layer epi-Ge. The single crystal germanium layers x-Ge, like the single crystal silicon layers, may be obtained by crystallizing amorphous germanium, and the seed of crystallization may be the crystal growth germanium layer epi-Ge.

Crystallization of the single crystal germanium layers x-Ge begins from a plurality of seeds of crystallization, and thus, a boundary between the single crystal germanium layers x-Ge may exist. Single crystal germanium layers x-Ge having more uniform crystal structures may be formed on each side of the boundary on the SiO₂ insulator.

Referring to FIG. 3B, a single crystal germanium substrate, according to at least this example embodiment, may include a SiO₂ insulator having a multi-layer (e.g., a dual layer) structure. For example, the SiO₂ insulator may be formed of SiO₂ and SiNₓ layers stacked on the single crystal germanium substrate in an island shape. For example, each portion of the multi-layer stack structure may be separated by a window or aperture (not shown). The window or aperture may be used for selective epitaxial growth, and may be formed in the SiO₂ insulator having the multi-layer structure. A crystal growth germanium layer epi-Ge may be formed in the window or aperture. A crystal boundary and a plurality of single crystal germanium layers x-Ge may be formed on the SiO₂ layer and the crystal growth germanium layer epi-Ge. In at least this example embodiment, the multi-layer structure may include two single crystal germanium layers.

A method of fabricating a single crystal silicon substrate having the above-described structure, according to an example embodiment, will be described in more detail below. According to example embodiments, a silicon wafer, a sapphire substrate or the like may be used to fabricate a single crystal silicon substrate, while a germanium or similar wafer may be used to fabricate a single crystal germanium substrate. A seed material and a crystallization target material may be, for example, silicon, germanium or the like.

A single crystal substrate, according to at least one example embodiment, having the above-described structure may include a laterally crystallized crystal layer. The lateral crystallization may be formed through an insulator having a window or aperture. Thus, a lateral crystallization induced layer, as described in accordance with at least some example embodiments, may correspond to an insulator exposing a surface of a substrate. The lateral crystallization induced layer may include the surface of the substrate exposed through the window or a material additionally formed through crystallization growth, for example, crystal growth silicon, crystal growth germanium or the like.

In a method of fabricating a single crystal substrate, according to at least some example embodiments, a stopper may be formed on a substrate. An amorphous layer may be formed to bury the stopper on the substrate. The amorphous layer may be melted and solidified to form a crystalline layer laterally crystallized and in parallel with the substrate. The crystalline layer may be polished up to an upper portion of the stopper buried in the crystalline layer.

The method described above may include a detailed lateral crystallization growth method described in more detail below, and thus, may not be limited by any known lateral crystallization method.

A method of fabricating a single crystal silicon substrate, according to an example embodiment will now be described.

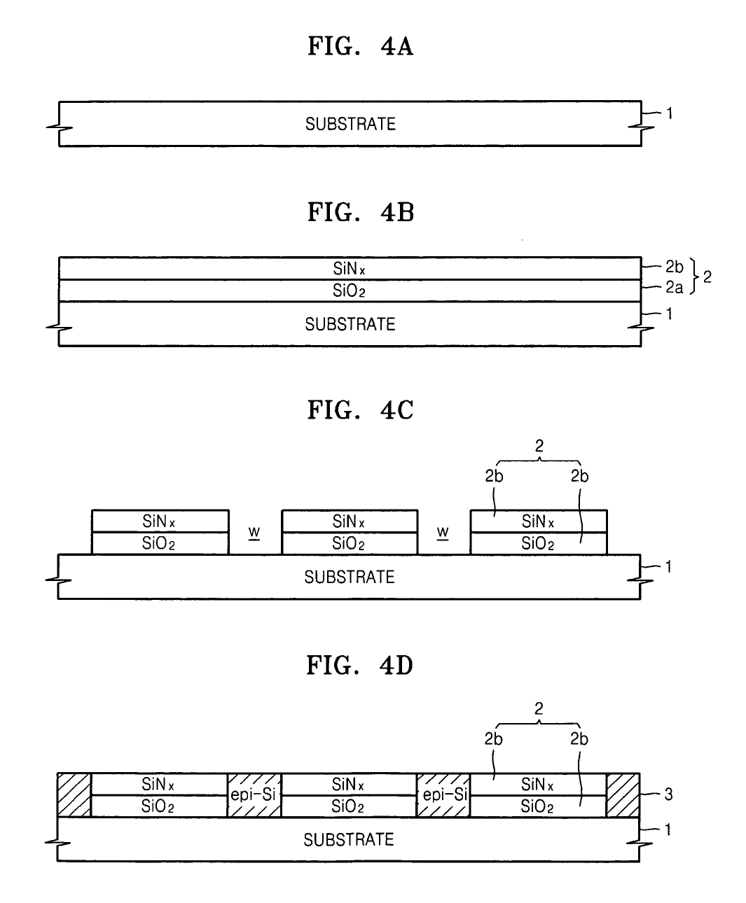

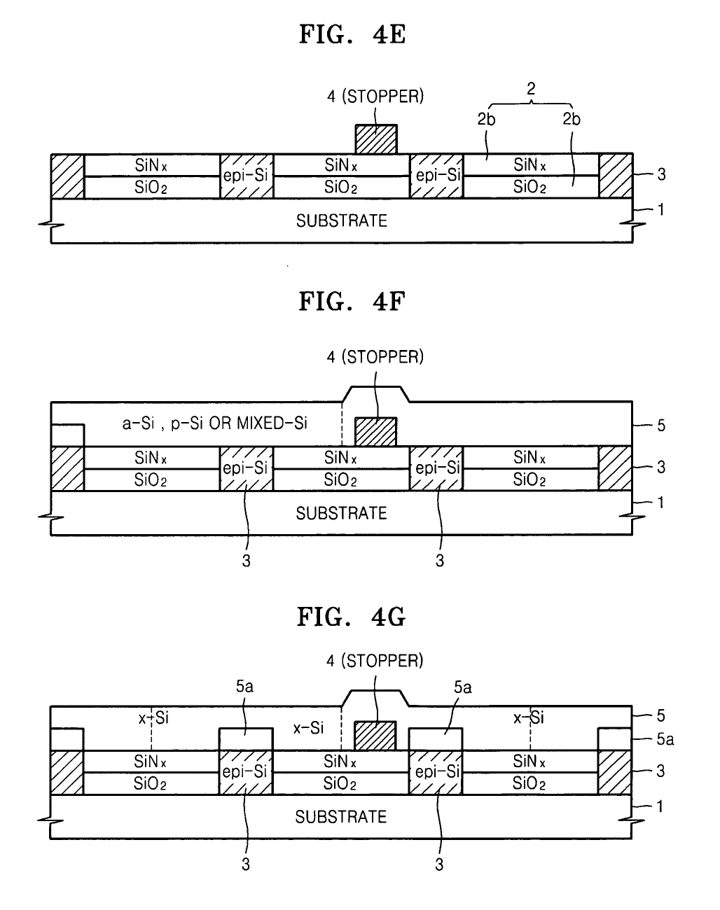

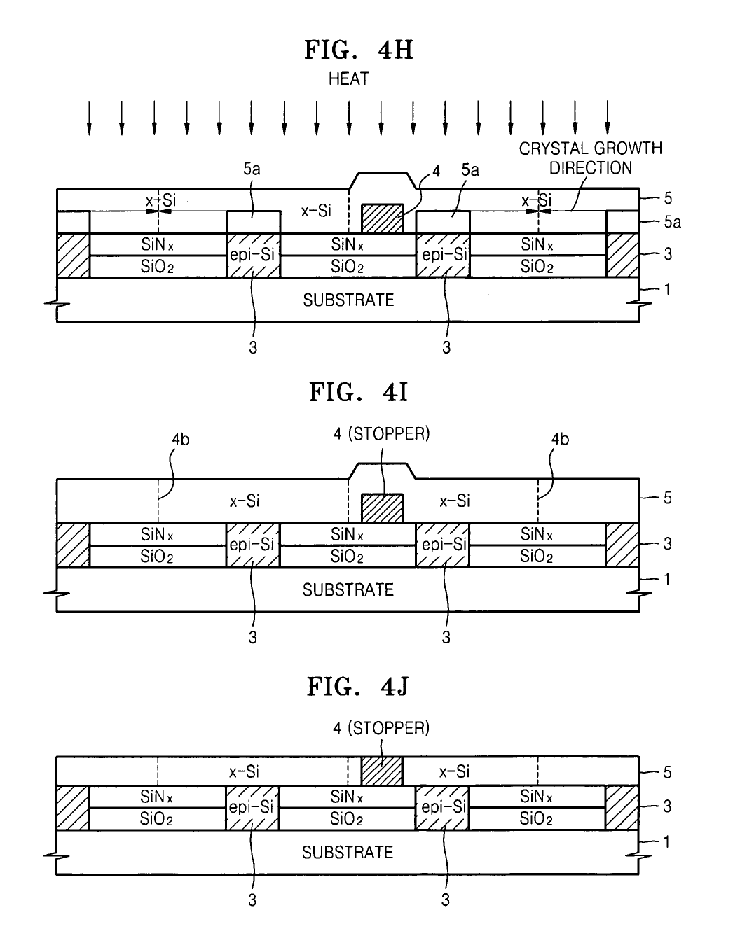

Referring to FIG. 4A, a substrate 1, such as, a silicon wafer, a sapphire substrate or the like may be provided. As shown in FIG. 4B, an insulator 2 may be formed on the substrate 1 using, for example, chemical vapor deposition (CVD), sputtering or the like. The insulator 2 may be an insulator having a single or multi-layer structure, for example, a stack of SiO₂ and Si₃N₄ layers. For example purposes, the insulator 2 of FIG. 4B is illustrated as having a multi-layer structure.

As illustrated in FIG. 4C, the insulator 2 may be patterned in an island shape forming at least one window W in the insulator 2. The window W exposes a portion of a surface of the substrate 1, and the exposed portion may be used as an epitaxial growth seed surface.

As illustrated in FIG. 4D, a crystal growth silicon layer 3 may be formed on the surface of the substrate 1 exposed through the window W using, for example, selective epitaxial growth or the like. A height of the crystal growth silicon layer 3 may be greater than or equal to the height of the insulator 2.

As illustrated in FIG. 4E, a stopper 4 may be formed on the insulator 2. The stopper 4 may limit the polishing depth as described above. The stopper 4 may be formed of, for example, silicon oxide, silicon nitride or the like. In at least this example embodiment, the insulator 2 and the stopper 4 may be fabricated simultaneously or concurrently. Alternatively, the stopper 4 may be formed before the crystal growth silicon layer 3 is formed and after the insulator 2 is formed.

As illustrated in FIG. 4F, an amorphous layer 5, burying the stopper 4, may be formed on the upper surface (e.g., the entire upper surface) of the substrate 1. For example, an amorphous layer 5 may be formed on the insulator 2 and the crystal growth silicon layer 3, to thickness sufficient to bury the stopper 4 and cover the entire surface of the insulator 2 and crystal growth silicon layers 3. In at least this example embodiment, the amorphous layer 5 may be formed of amorphous silicon (a-Si), polycrystalline silicon (a-Si) formed by a difference in a deposition method of silicon, a silicon combination of amorphous silicon and crystalline silicon, any suitable material or combination of materials.

As illustrated in FIG. 4G, annealing may be performed in a general furnace to induce solid phase crystallization (SPC). For example, the density of the amorphous layer 5 may be increased and remaining gas or gases may be removed during annealing. At least one partially crystallized area 5a may be formed on the crystal growth silicon layer 3 through annealing.

As illustrated in FIG. 4H, the amorphous layer 5 may be heated at or near a melting temperature and cooled to induce crystallization of a silicon material. In at least this example embodiment, an excimer laser may be used as a heat source; however, any suitable heat source may be used. In at least one example embodiment, the amorphous layer 5 may be heated (e.g., melted) using an excimer laser annealing (ELA) method and then cooled to crystallize or re-crystallize the silicon. Crystal growth may begin from an upper portion of the crystal growth silicon layer 3, which may function as a seed layer in a lateral direction parallel with the substrate 1 as indicated by the arrows in FIG. 4G.

In FIG. 4I, the crystal growth is complete, and a plurality of single crystal silicon layers 5 are formed on the surface of the substrate 1. Each of the plurality of single crystal layers 5 is separated by a boundary 4b. Because the single crystal silicon layers 5 formed using the above-described processes are laterally crystallized, surfaces of the single crystal silicon layers 5 may be relatively rough, and thus, may be polished using chemical mechanical polishing (CMP) or the like.

As shown in FIG. 4J, the single crystal silicon layers 5 may be polished using CMP to a thickness defined by the stopper 4. The stopper 4 may suppress (e.g., inhibits and/or prevent) excessive polishing and/or estimate a polishing degree during polishing of the single crystal silicon layers 5.

A method of fabricating the single crystal germanium, according to at least some example embodiments, has similar process conditions to the example embodiment of a method of fabricating the single crystal silicon, as described above. However, a germanium substrate may be used instead of a silicon substrate or a sapphire substrate and a seed layer and a crystal target material may be formed of germanium materials.

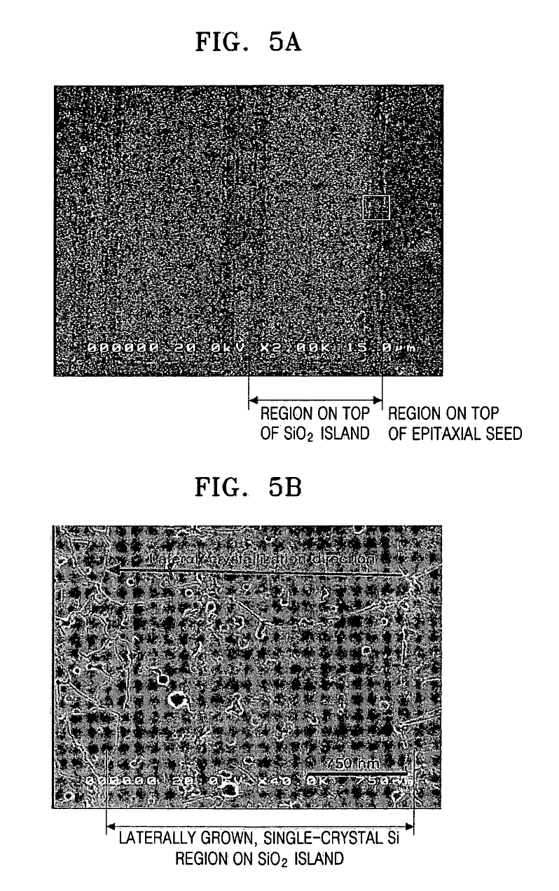

FIG. 5A is a scanning electronic microscopy (SEM) image illustrating a fabricated single crystal silicon substrate, and FIG. 5B is an enlarged image of a square portion of the SEM image illustrated in FIG. 5A, according to an example embodiment.

In a first sample, a SiO₂ insulator is relatively wide and single crystal silicon is not completely formed. Complete crystallization of the single crystal silicon is related to a gap between crystal growth silicon portions or a width of a silicon oxide insulator. Thus, the gap or the width may be reduced to successfully crystallize the single crystal silicon. The melting laser and the cooling may limit a length of lateral growth. Also, if the width of the silicon oxide insulator is about two times the length of the silicon oxide insulator, polycrystalline silicon may be formed by nucleation of liquid silicon in an intermediate area on the silicon oxide insulator, which is not laterally crystallized. Nucleation of liquid silicon may occur relatively frequently.

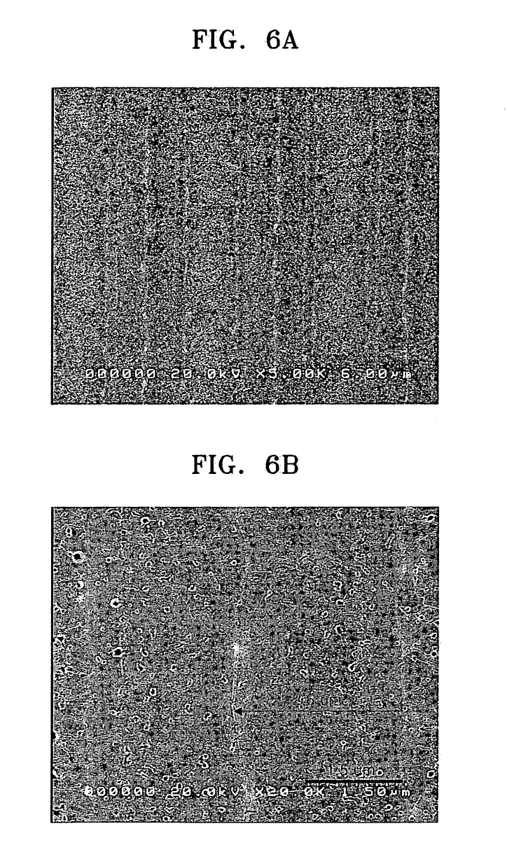

FIG. 6A is an SEM image illustrating a second sample of a single crystal silicon successfully crystallized above an insulator and FIG. 6B is an enlarged SEM image of the second sample, according to an example embodiment. As shown in FIGS. 6A and 6B, single crystal silicon grown from a crystal growth silicon may be formed on an insulator to form a boundary (vertical part shown in FIG. 6B) having a width of about 2.6 microns.

As described above, according to at least some example embodiments, a single crystal silicon substrate and a single crystal germanium substrate having smooth surfaces may be more easily fabricated at a reduced cost. Thus, cost for fabricating a device may be reduced.

At least some example embodiments may be applied in various fields requiring a single crystal silicon substrate or a single crystal germanium substrate having a silicon on insulator (SOI) structure. For example, methods of fabricating the single crystal substrate, according to at least some example embodiments, may be applied to thin film transistors (TFTs), electronic parts using silicon (e.g., solar batteries) and Ge, etc.

Although example embodiments have been described with regard to silicon and Germanium, any suitable semiconductor material or compound may be used. For example, Group IV elemental semiconductors, such as, Diamond (C), Silicon (Si) or Germanium (Ge); Group IV compound semiconductors, such as, Silicon carbide (SiC) Silicon germanide (SiGe); III-V semiconductors, such as, Aluminum antimonide (AlSb), Aluminum arsenide (AlAs), Aluminum nitride (AlN), Aluminum phosphide (AlP), Boron nitride (BN), Boron arsenide (BAs), Gallium antimonide (GaSb), Gallium arsenide (GaAs), Gallium nitride (GaN), Gallium phosphide (GaP), Indium antimonide (InSb), Indium arsenide (InAs), Indium nitride (InN), Indium phosphide (InP); III-V ternary semiconductor alloys, such as, Aluminum gallium arsenide (AlGaAs, AlxGa1-xAs), Indium gallium arsenide (InGaAs, InxGa1-xAs), Aluminum indium arsenide (AlInAs), Aluminum indium antimonide (AlInSb), Gallium arsenide nitride (GaAsN), Gallium arsenide phosphide (GaAsP), Aluminum gallium nitride (AlGaN), Aluminum gallium phosphide (AlGaP), Indium gallium nitride (InGaN), Indium arsenide antimonide (InAsSb), Indium gallium antimonide (InGaSb); III-V quaternary semiconductor alloys, such as, Aluminum gallium indium phosphide (AlGaInP, also InAlGaP, InGaAlP, AlInGaP), Aluminum gallium arsenide phosphide (AlGaAsP), Indium gallium arsenide phosphide (InGaAsP), Aluminum indium arsenide phosphide (AlInAsP), Aluminum gallium arsenide nitride (AlGaAsN), Indium gallium arsenide nitride (InGaAsN), Indium Aluminum arsenide nitride (InAlAsN); III-V quinary semiconductor alloys, such as, Gallium indium nitride arsenide antimonide (GaInNAsSb); or any other semiconductor material or compound may be used in conjunction with at least some example embodiments.

While example embodiments have been particularly shown and described with reference to the example embodiments shown in the drawings, it will be understood by those of ordinary skill in the art that various changes in form and details may be made therein without departing from the spirit and scope of the present invention as defined by the following claims.

What is claimed is:

1. A crystal substrate comprising:
a crystalline substrate;
a laterally-crystallized crystalline layer in parallel with the crystalline substrate; and
a polishing stopper buried in the laterally crystallized crystalline layer for limiting a polishing depth of the laterally crystallized crystalline layer.

2. The crystal substrate of claim 1, further including
an insulator arranged between the crystalline substrate and the laterally crystallized crystalline layer for inducing lateral growth of the laterally crystallized crystalline layer.

3. The crystal substrate of claim 2, wherein a window is formed in the insulator to expose the crystalline substrate.

4. The crystal substrate of claim 2, wherein a seed layer is formed in the window using selective epitaxial growth.

5. The crystal substrate of claim 1, wherein the crystalline substrate is a sapphire substrate, a silicon substrate or a germanium substrate.

6. The crystal substrate of claim 2, wherein the insulator is a silicon oxide (SiO₂) insulator.

7. The crystal substrate of claim 2, wherein the insulator has a stack structure.

8. The crystal substrate of claim 7, wherein the insulator further includes,
a SiO₂ insulator, and
a silicon nitride layer stacked on the SiO₂ insulator.

9. A method of fabricating a crystal substrate, the method comprising:
forming a stopper on a crystalline substrate;
forming an amorphous layer burying the stopper on the crystalline substrate;
melting and solidifying the amorphous layer to form a crystalline layer crystallized in parallel with the crystalline substrate; and
polishing the crystalline layer to an upper portion of the stopper.

10. The method of claim 9, further including,
forming an insulator having a window on the crystalline substrate to expose a surface of the crystalline substrate before forming the stopper.

11. The method of claim 9, further including,
forming an epitaxial growth seed layer on a portion of the surface of the crystalline substrate exposed through the window.

12. The method of claim 9, wherein the crystalline substrate is a silicon substrate, a sapphire substrate or a germanium substrate.

13. The method of claim 10, wherein the insulator includes at least one of a SiO₂ layer and a SiNₓ layer.

14. The method of claim 10, wherein the insulator is formed to have a stack structure.

15. The method of claim 14, wherein the stack structure includes a SiO₂ layer and a SiNx layer stacked on the SiO₂ layer.

16. The method of claim 10, wherein the forming of the insulator further includes,
alternately stacking layers of SiO₂ and SiNₓ.

17. The method of claim 9, wherein the amorphous layer is an amorphous silicon layer or an amorphous germanium layer.

18. The method of claim 9, wherein the amorphous layer is a polycrystalline silicon layer or a polycrystalline germanium layer.

19. The method of claim 9, wherein the amorphous layer includes polycrystalline silicon.

20. The method of claim 9, wherein the amorphous layer is melted using excimer laser annealing.

21. The method of claim 9, wherein the insulator is formed using chemical vapor deposition or sputtering.

22. The method of claim 9, further including,
annealing a crystallization target material after melting but before solidifying the amorphous layer.
